(19) United States
(12) Patent Application Publication
(10) Pub. No.: US 2007/0231996 A1
(43) Pub. Date: Oct. 4, 2007

(54) Plasma display panel

(76) Inventors: Se-Jong Kim, Suwon-si (KR); Hyun Soh, Suwon-si (KR); Yun-Hee Kim, Suwon-si (KR); Kyoung-Doo Kang, Suwon-si (KR); Hyun Kim, Suwon-si (KR); Jin-Won Han, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/729,838

(22) Filed: Mar. 30, 2007

(30) Foreign Application Priority Data
Mar. 31, 2006 (KR) 10-2006-0029716

(51) Int. Cl. H01L 21/8242

(52) U.S. Cl. 438/251

(57) ABSTRACT

A plasma display panel includes front and rear substrates parallel to one another, a plurality of discharge electrode pairs on the front substrate, a plurality of discharge cells between the front and rear substrates, a front dielectric layer having a plurality of grooves on the discharge electrode pairs, and a protective layer on the front dielectric layer, the protective layer having first protective layer portions on a first front dielectric layer portion of the front dielectric layer, second protective layer portions on a second front dielectric layer portion of the front dielectric layer, and third protective layer portions, wherein at least one thickness of the first protective layer portions and the third protective layer portions is larger than a thickness of the second protective layer portions.

### BACKGROUND OF THE INVENTION

1. Field of the Invention

The present invention relates to a plasma display panel. In particular, the present invention relates to a plasma display panel exhibiting improved luminous efficiency.

2. Description of the Related Art

In general, plasma display panels (PDP) are flat display devices employing discharge gas between two substrates with a plurality of electrodes to form images. In particular, a predetermined amount of electricity may be applied to the electrodes to trigger ultraviolet (UV) emission and excite a phosphor layer formed in a predetermined pattern to emit light and, thereby, form images.

The conventional PDP may include upper and lower panels parallel to each other, a plurality of discharge electrode pairs having transparent and bus electrodes on a front substrate of the upper panel, a plurality of address electrodes on a rear substrate of the lower panel positioned perpendicularly to the plurality of discharge electrode pairs, front and rear dielectric layers on the front and rear substrates, respectively, a protective layer on the front dielectric layer, and a plurality of barrier ribs on a front surface of the rear dielectric layer. The conventional PDP may further include a phosphor layer on both side surfaces of the barrier ribs and a portion of the rear dielectric layer.

However, the conventional PDP requires a high driving voltage and exhibits low luminous efficiency.

Accordingly, there exists a need to provide a PDP with a structure capable of operating with lower driving voltage, while exhibiting enhanced luminous efficiency.

### SUMMARY OF THE INVENTION

The present invention is therefore directed to a plasma display panel (PDP), which substantially overcomes one or more of the disadvantages of the related art.

It is therefore a feature of an embodiment of the present invention to provide a PDP having improved luminous efficiency.

It is another feature of an embodiment of the present invention to provide a PDP having a reduced discharge voltage.

At least one of the above and other features and advantages of the present invention may be realized by providing a plasma display panel (PDP), including front and rear substrates parallel to one another, a plurality of discharge electrode pairs on the front substrate, a plurality of discharge cells between the front and rear substrates, a front dielectric layer having a plurality of grooves on the discharge electrode pairs, and a protective layer on the front dielectric layer, the protective layer having first protective layer portions on a first front dielectric layer portion of the front dielectric layer, second protective layer portions on a second front dielectric layer portion of the front dielectric layer, and third protective layer portions, wherein at least one thickness of the first protective layer portions and the third protective layer portions is larger than a thickness of the second protective layer portions. A surface roughness of the second front dielectric layer portion may be lower than a surface roughness of the first front dielectric layer portion.

Each of the grooves may correspond to a respective discharge cell. Each of the grooves may have a rectangular cross-section. Each of the grooves may be between pairs of the discharge electrode pairs. The grooves may be parallel to bus electrodes of the discharge electrodes. Each discharge electrode may include a T-shaped transparent electrode.

The grooves may be in communication with the front substrate. The first protective layer portions may be on sidewalls of the grooves, the second protective layer portions may be on the second front dielectric layer portion of the front dielectric layer, and the third protective layer portions may be on the front substrate. A surface roughness of the front substrate may be larger than a surface roughness of a second front dielectric layer portion of the front dielectric layer.

The third protective layer portions may be in communication with a third front dielectric layer portion. A surface roughness of the second front dielectric layer portion may be lower than a surface roughness of the third front dielectric layer portion.

The first protective layer portions, the second protective layer portions, and the third protective layer portions may substantially include the same material. The first protective layer portions, the second protective layer portions, and the third protective layer portions may include magnesium oxide (MgO).

In another aspect of the present invention, there is provided, a plasma display panel (PDP), including a rear substrate, a front substrate in parallel to the rear substrate, a plurality of barrier ribs between the front and rear substrates defining a plurality of discharge cells, a plurality of discharge electrode pairs spaced apart from one another on the front substrate, a front dielectric layer having a first front dielectric layer and a second front dielectric layer portion, a plurality of grooves in the front dielectric layer, a protective layer on the front dielectric layer, the protective layer having first protective layer portions on sidewalls of the grooves, second protective layer portions on a second front dielectric layer portion of the front dielectric layer, and third protective layer portions on horizontal surfaces of the grooves, and wherein at least one thickness of the first protective layer portions and the third protective layer portions is larger than a thickness of the second protective layer portions, a plurality of address electrodes on the rear substrate, a plurality of phosphor layers inside the discharge cells, and a discharge gas in the discharge cells. A surface roughness of the second front dielectric layer portion of the front dielectric layer may be lower than a surface roughness of a first front dielectric layer of the front dielectric layer.

The grooves may be in communication with the front substrate. A surface roughness of the front substrate may be larger than a surface roughness of a second front dielectric layer portion of the front dielectric layer.

Each of the grooves may be between pairs of discharge electrodes. Each of the grooves may be between an X electrode of one pair of discharge electrodes and a Y electrode of another pair of discharge electrodes. The grooves may be discontinuously formed in each of the discharge cells. One groove may be formed in each of the discharge cells.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates an exploded perspective view of a PDP according to an embodiment of the present invention;

FIG. 2 illustrates a schematic view of an exemplary configuration of grooves with respect to discharge cells and electrodes in the PDP illustrated in FIG. 1;

FIG. 3 illustrates a cross-sectional view taken along line III-III of FIG. 1;

FIG. 4 illustrates an enlarged view of portion A of FIG. 2;

FIG. 5 illustrates a schematic view of an exemplary configuration of grooves with respect to discharge cells and electrodes according to another embodiment of the present invention; and

FIG. 6 illustrates a cross-sectional view of a PDP according to another embodiment of the present invention.

### DETAILED DESCRIPTION OF THE INVENTION

Korean Patent Application No. 10-2006-0029716, filed on Mar. 31, 2006, in the Korean Intellectual Property Office, and entitled: “Plasma Display Panel,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

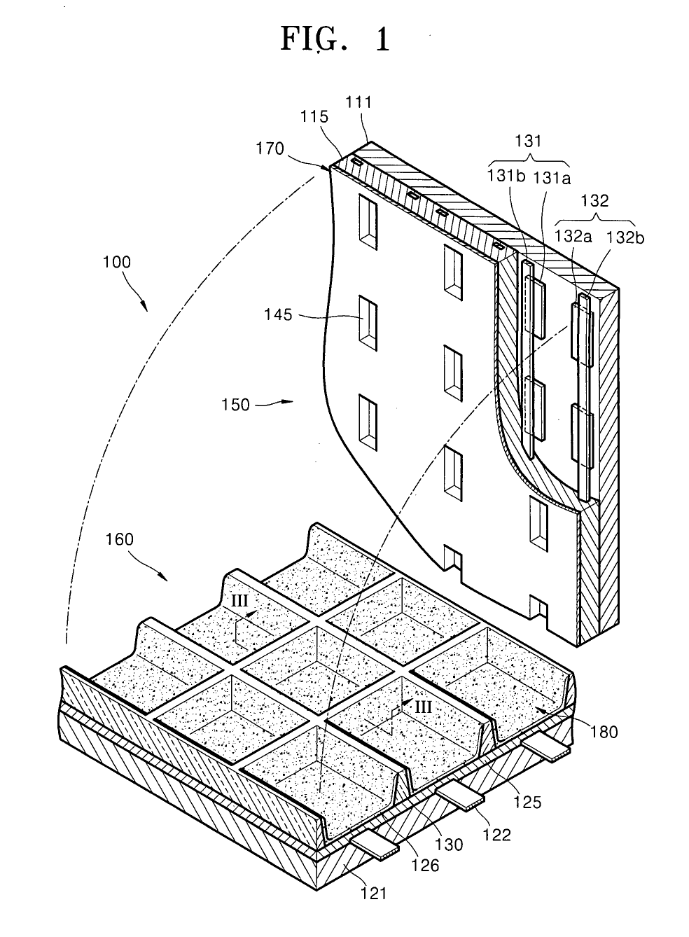

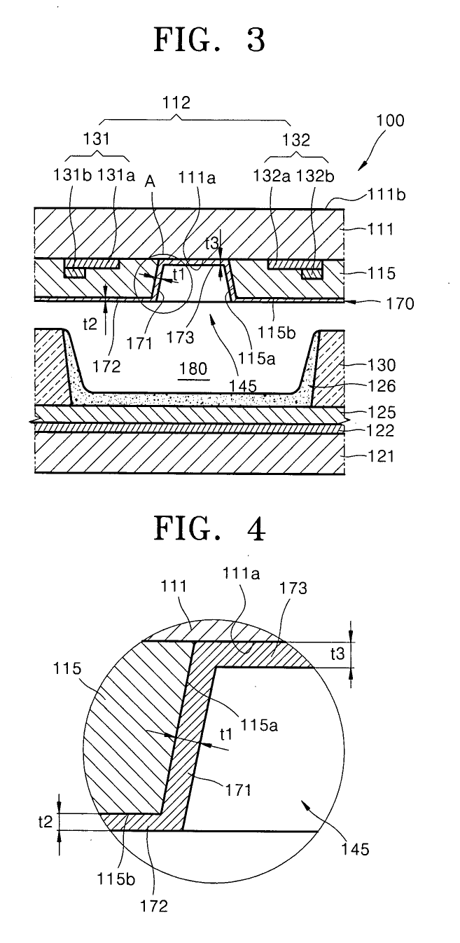

An exemplary embodiment of a plasma display panel (PDP) according to the present invention will be described more fully with reference to FIGS. 1-4.

As illustrated in FIG. 1, a plasma display panel (PDP) 100 according to an embodiment of the present invention may include upper and lower panels 150 and 160, respectively, in parallel to one another. The upper panel 150 may include a front substrate 111, a plurality of discharge electrode pairs 112, a front dielectric layer 115, and a protective layer 170. The lower panel 160 may include a rear substrate 121, a plurality of address electrodes 122, a rear dielectric layer 125, barrier ribs 130, and phosphor layers 126.

The front and rear substrates 111 and 121 may be formed of glass having good light transmission and be colored in order to improve bright room contrast. The front substrate 111 of the upper panel 150 may be positioned in parallel to the rear substrate 121 of the lower panel 160, so that a predetermined gap between the front and rear substrates 111 and 121 may define a discharge space. The front substrate 111 may include a rear surface 111a and a front surface 111b, so that the rear surface 111a may be between the front substrate 111 and the rear substrate 121.

The plurality of discharge electrode pairs 112 of the upper panel 150 according to an embodiment of the present invention may be disposed on the rear surface 111a of the front substrate 111, i.e., on a plane parallel to the front substrate 111, and in parallel to one another. However, other electrode configurations, e.g., the plurality of discharge electrode pairs 112 may be spaced apart from one another on a plane perpendicular to the front substrate 111, are not excluded from the scope of the present invention. Each pair of the plurality of discharge electrode pairs 112 may include an X electrode 131 and a Y electrode 132.

Each pair of discharge electrodes, i.e., X electrode 131 and Y electrode 132, may include first and second transparent electrodes 131a and 132a, respectively, and first and second bus electrodes 131b and 132b, respectively. The first and second transparent electrodes 131a and 132a may be formed of a transparent material, e.g., indium tin oxide (ITO), thereby triggering a large voltage drop resulting in increased power consumption and decreased response speed. Accordingly, the first and second bus electrodes 131b and 132b may be formed as single-layered or multi-layered metal, e.g., silver (Ag), aluminum (Al) or copper (Cu), on outer edges of the first and second transparent electrodes 131a and 132b. The first and second transparent electrodes 131a and 132a and the first and second bus electrodes 131b and 132b may be formed using photo-etching or photolithography.

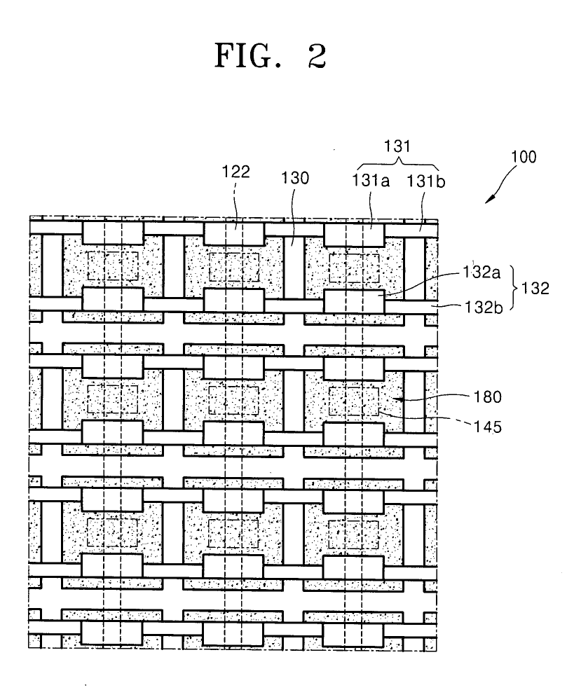

In particular, as illustrated in FIG. 2, the first and second bus electrodes 131b and 132b may be formed parallel to one another and positioned across respective discharge cells 180 along the front substrate 111, so that each bus electrode 131b and 132b may extend across a row of respective discharge cells 180. The first and second transparent electrodes 131a and 132a may be formed as discontinuous segments and disposed in each discharge cell 180 and in communication with a respective first and second bus electrode 131b and 132b, so that at least one side of each transparent electrode 131a and 132a may be connected to a respective first and second bus electrode 131b and 132b. The first and second transparent electrodes 131a and 132a may be either parallel or perpendicular to the respective first and second bus electrodes 131b and 132b. If the first and second transparent electrodes 131a and 132a are perpendicular to the respective first and second bus electrodes 131b and 132b, one side of each first and second transparent electrodes 131a and 132a may be directed toward a center of the respective discharge cell 180.

The front dielectric layer 115 of the front panel 150 according to an embodiment of the present invention may be formed of lead oxide (PbO), bismuth oxide (B2O3) or silicon oxide (SiO2) on the rear surface 111a of the front substrate 111 to coat the plurality of discharge electrode pairs 112. The front dielectric layer 115 may minimize electrical shorts by preventing electrical contact between the X electrode 131 and the Y electrode 132 and minimize collisions between charged particles and the discharge electrode pairs 112. The front dielectric layer 115 may also induce charges.

The front dielectric layer 115 may include first front dielectric layer portions 115a and second front dielectric layer portions 115b to define a plurality of grooves 145 in communication with the rear surface 111a of the front substrate 111.

In particular, the first front dielectric layer portions 115a may extend from a rear surface of the front dielectric layer 115 toward the rear surface 111a of the front substrate 111 to form sidewalls of a plurality of openings within the front dielectric layer 115 to define the plurality of grooves 145. Formation of the plurality of grooves 145 in the front dielectric layer 115 may reduce a thickness of the front dielectric layer 115 and, thereby, improve transmittance of visible light through the grooves 145 toward the front substrate 111. The second front dielectric layer portions 115b may be parallel to the front substrate 111 and coat the X and Y electrodes 131 and 131. In other words, the second front dielectric layer portions 115b may be around the grooves 145, so that the groves 145 and the first front dielectric layer portions 115a are excluded. A surface roughness of the first front dielectric layer portions 115a may be larger than a surface roughness of the second front dielectric layer portions 115b, as will be discussed in more detail below.

The plurality of grooves 145 may be formed in the front dielectric layer 115 between the pairs of the plurality of discharge electrodes 112, so that each groove 145 may be formed between an X electrode 131 of one pair of the discharge electrodes 112 and a Y electrode 132 of another pair of the discharge electrodes 112. Accordingly, each groove 145 may correspond to a respective discharge cell 180. Additionally, each groove 145 may have any polygonal cross-section as determined by one of ordinary skill in the art, e.g., rectangular.

Without intending to be bound by theory, it is believed that formation of the grooves between the plurality of pairs of discharge electrodes 112 is advantageous because an amount of charge is higher in the discharge space between the X and Y electrodes 131 and 132, thereby increasing an electric field value in the grooves 145. The increased electric field may increase the discharge in the grooves 145 and, thereby reduce the discharge voltage, while increasing brightness and luminous efficiency, of the PDP.

The protective layer 170 of the front panel 150 according to an embodiment of the present invention may be formed on the front dielectric layer 115. In particular, the protective layer 170 may include first protective layer portions 171 having a thickness t1, second protective layer portions 172 having a thickness t2, and third protective layer portions 173 having a thickness t3. The first, second and third protective layer portions 171, 172 and 173 may be in communication with the first front dielectric layer portions 115a, second front dielectric layer portions 115b, and rear surface 111a of the front substrate 111, respectively. The protective layer 170 may minimize collisions of charged particles and/or electrons with the front dielectric layer 115 and, thereby, minimize damage to the front dielectric layer 115. Additionally, the protective layer 170 may facilitate plasma discharge efficiency by emitting a large amount of secondary electrons during a discharge.

The thicknesses t1 and t3 of the first and third protective layer portions 171 and 173 may be larger than the thickness t2 of the second protective layer portions 172. In particular, the first and third protective layer portions 171 and 173 may be in communication with an interior of the grooves 145 and, thereby, define a space having a relatively high discharge. Accordingly, increased thicknesses t1 and t3 of the first and third protective layer portions 171 and 173 may be advantageous to increase an amount of secondary electrons within the discharge space, decrease a discharge voltage, and improve luminous efficiency and brightness of the PDP. Even though the thickness t2 of the second protective layer portions 172 may be equal to the thicknesses t1 and t3 of the first and third protective layer portions 171 and 173, respectively, an increased thickness t2 may enhance overall manufacturing costs and time of the protective layer 170. The thickness t1 and t3 of the first and third protective layer portions 171 and 173 may be substantially equal, or they may have different values.

The protective layer 170 may be formed by deposition of a material having a high secondary electron emission factor and a high visible light transmittance, e.g., magnesium oxide (MgO). In particular, forming the first, second and third protective layer portions 171, 172 and 173 to have different thicknesses, may include controlling a surface roughness of the front dielectric layer 115 and the front substrate 111 via a re-thermal treatment processing operation.

More specifically, a dielectric paste may be printed onto the rear surface 111a of the front substrate 111 to form a dielectric paste layer. Next, the grooves 145 maybe formed in the dielectric paste layer via etching, sandblasting or photosensitive sheet. Once the grooves 145 are formed, a re-thermal treatment process may be performed at a low temperature to increase a surface roughness of the first front dielectric layer portions 115a and the rear surface 111a of the front substrate portions 111a as compared to a surface roughness of the second front dielectric layer portions 115b. The low temperature employed for the re-thermal treatment may be a temperature below a baking temperature, i.e., about 350° C. to about 450° C. A high temperature may be the baking temperature, i.e., about 500° C. to about 580° C.

The address electrodes 122 of the lower panel 160 according to an embodiment of the present invention may be disposed on the rear substrate 121, i.e., on a plane parallel to the rear substrate 121, and in parallel to one another. Additionally, the address electrodes 122 may extend across the discharge cells 180 perpendicularly to the plurality of pairs of discharge electrode 112. The address electrodes 122 may trigger an address discharge between the Y electrodes 132 and the address electrodes 122, so that a voltage required for a sustain discharge between the X electrodes 131 and the Y electrodes 132 may be reduced.

The rear dielectric layer 125 of the lower panel 160 according to an embodiment of the present invention may be formed of lead oxide (PbO), bismuth oxide (B₂O₃) or silicon oxide (SiO₂) on the rear substrate 121 to coat the address electrodes 122. The rear dielectric layer 125 may prevent collisions between charged particles or electrons and the address electrodes 122 and minimize damage of the address electrodes 122. The rear dielectric layer 125 may also induce charges.

The barrier ribs 130 of the lower panel 160 according to an embodiment of the present invention may be disposed between the front and rear substrates 111 and 121. More specifically, the barrier ribs 130 may be disposed on the rear dielectric layer 125 and partition the discharge space into a plurality of discharge cells 180, so that no optical/electrical contact may be formed between the discharge cells 180. The barrier ribs 130 may be positioned to form a plurality of discharge cells 180 arranged in a matrix pattern, so that each discharge cell 180 may have a cross-section as determined by one of ordinary skill in the art, e.g., rectangular, triangular, pentagonal, circular, elliptical, striped-patterned, waffle-patterned, delta-patterned, and so forth.

The phosphor layers 126 of the lower panel 160 according to an embodiment of the present invention may be disposed on side surfaces of the barrier ribs 130 and on the front surface of the rear dielectric layer 125. The phosphor layers 126 may include components capable of emitting visible light in response to excitation by ultraviolet light. In particular, the phosphor layers 126 may include a red light-emitting phosphor, e.g., Y(V,P)O₄:Eu, a green light-emitting phosphor, e.g., Zn₂SiO₄:Mn and YBO₃:Tb, and a blue light-emitting phosphor, e.g., BAM:Eu.

The PDP 100 according to an embodiment of the present invention may also include a discharge gas in the discharge cells 180. The discharge gas may include neon (Ne), xenon (Xe), or a mixture thereof.

The PDP 100 according to an embodiment of the present invention may further include a sealing member (not shown) to seal the front substrate 111 and the rear substrate 121. For example, a frit glass may be formed on edges of the front substrate 111 and the rear substrate 121 to seal the discharge gas in the discharge cells 180 between the front and rear substrates 111 and 121.

The PDP 100 according to an embodiment of the present invention may operate as follows. An address discharge voltage may be applied between the address electrodes 122 and the Y electrodes 132 to trigger an address discharge and, thereby, select discharge cells 180 to be operated, i.e., discharge cells 180 to emit light. Next, a sustain discharge voltage may be applied between pairs of X electrodes 131 and Y electrodes 132 positioned along selected discharge cells 180 to trigger discharge voltage in the selected discharge cells 180.

Without intending to be bound by theory, it is believed that upon application of the sustain discharge voltage to the selected discharge cells 180, an increased electric field may be generated in the plurality of grooves 145, i.e., respective selected discharge cells 180, thereby reducing the produced discharge voltage and increasing luminance. In particular, forming the plurality of grooves 145 to correspond to the discharge cells 180 and between the pairs of the discharge electrodes 112 may reduce a discharge path between the X electrode 131 and the Y electrode 132 and increase an amount of charged particles therebetween, so that the electric field therebetween may increase. Additionally, a large amount of secondary electrons may be generated by the first and second protective layer portions 171 and 173, thereby increasing a discharge speed.

The reduced discharge voltage may trigger emission of UV rays that, in turn, may excite the phosphor layers 126 in the discharge cells 180. The phosphor layers 126 may reach an excitation state due to energy absorption. As the energy level of the excited phosphor layers 126 declines, visible light may be emitted from the phosphor layers 126 and transmitted through the front dielectric layer 115 and the front substrate 111 toward an exterior of the PDP to form images. Due to the reduced discharge voltage, the luminous efficiency of the PDP 100 may be improved.

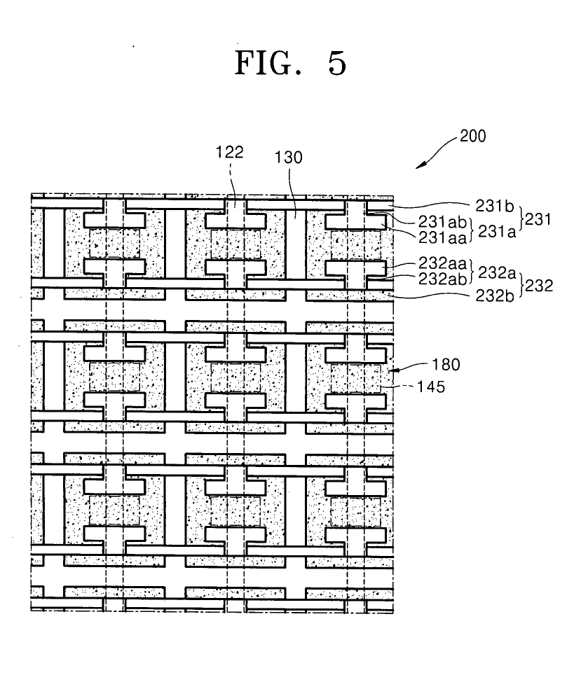

According to another embodiment of the present invention illustrated in FIG. 5, a plasma display panel (PDP) 200 may be similar to the PDP 100 described previously with respect o FIGS. 1-4, with the exception of having “T-shaped” first and second transparent electrodes 231a and 232a of respective X electrodes 231 and Y electrodes 232, as illustrated in FIG. 5. In particular, each of the X and Y electrodes 231 and 232 may include a plurality of transparent electrodes 231a and 232a, respectively, and bus electrodes 231b and 232b, respectively. Each transparent electrode 231a of the X electrode 231 may include a discharge portion 231aa and a connection portion 232ab positioned perpendicularly to one another to form a “T-shape.” The discharge portion 231aa may be parallel to the bus electrode 231b of the X electrode 231 and spaced apart therefrom toward a center of the discharge cell 180. The connection portion 231ab may connect the discharge portion 231aa and the bus electrode 231b of the X electrode 231, i.e., to form an inverted “T-shape” with the discharge portion 231aa. Similarly, each transparent electrode 232a of the Y electrode 232 may include a discharge portion 232aa and a connection portion 232ab structured similarly to the discharge portion 231aa and connection portion 231ab of the transparent electrode 231a of the X electrode 231, with the exception that the connection portion 232ab may connect the discharge portion 232aa and the bus electrode 232b of the Y electrode 232 to form an upright “T-shape.” The discharge portions 231aa and 232aa of the X electrode 231 and the Y electrode 232, respectively, may have a gap therebetween, thereby reducing a discharge voltage. Further, the structures of the X and Y electrodes 231 and 232 include transparent electrodes 231a and 232a with a reduced area, thereby enhancing visible light transmittance.

Other structural details of the PDP 200 may be similar to the structural details of the PDP 100 described previously with respect to FIGS. 1-4 and, therefore, will not be repeated herein.

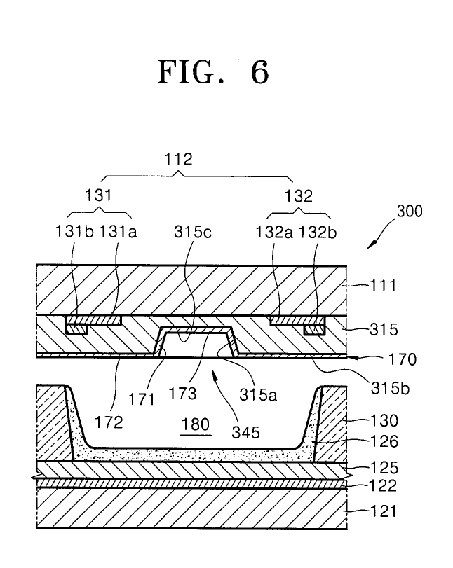

According to yet another embodiment of the present invention illustrated in FIG. 6, a plasma display panel (PDP) 300 may be similar to the PDP 100 or PDP 200 described previously with respect o FIGS. 1-5, with the exception of having a plurality of grooves 345 formed in a front dielectric layer 315. In particular, the grooves 345 may be formed only to a predetermined depth in the front dielectric layer 315, so that the grooves 345 are not in communication with the rear surface 111a of the front substrate 111.

In this respect, it should be noted that the front dielectric layer 315 may include a first front dielectric layer portion 315a, a second front dielectric layer portion 315b, and a third front dielectric layer portion 315c. The first and second front dielectric layer portions 315a and 315b may be similar to the first and second front dielectric layer portions 115a and 115b described previously with respect to the PDP 100 of FIGS. 1-4. The third front dielectric layer portions 315c may connect two first front dielectric layer portions 315a and be in communication with the rear surface 111a of the front substrate 111. Accordingly, the third protective layer portions 173 may be disposed on the third front dielectric layer portion 315c, as further illustrated in FIG. 6. Other structural details of the front dielectric layer 315 and the grooves 345 may be similar to the structural details of the front dielectric layer 115 and the grooves 145 described previously with respect to FIGS. 1-5 and, therefore, will not be repeated herein.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A plasma display panel (PDP), comprising:
a pair of substrates parallel to one another;
a plurality of discharge electrode pairs on the one of the substrates;
a plurality of discharge cells between the substrates;
a dielectric layer having a plurality of grooves and covering the discharge electrode pairs; and
a protective layer having first protective layer portions on a first dielectric layer portion of the dielectric layer, second protective layer portions on a second dielectric layer portion of the dielectric layer, and third protective layer portions,
wherein at least one thickness of the first protective layer portions and the third protective layer portions is larger than a thickness of the second protective layer portions.

2. The PDP as claimed in claim 1, wherein a surface roughness of the second dielectric layer portion is lower than a surface roughness of the first dielectric layer portion.

3. The PDP as claimed in claim 1, wherein the grooves are in communication with the substrate on which the discharge electrode pairs are arranged.

4. The PDP as claimed in claim 3, wherein the first protective layer portions are on sidewalls of the grooves, the second protective layer portions are on the second dielectric layer portion of the dielectric layer, and the third protective layer portions are on the substrate on which the discharge electrode pairs are arranged.

5. The PDP as claimed in claim 4, wherein a surface roughness of the substrate on which the discharge electrode pairs are arranged is larger than a surface roughness of the second dielectric layer portion of the dielectric layer.

6. The PDP as claimed in claim 1, wherein the third protective layer portions are in communication with a third dielectric layer portion.

7. The PDP as claimed in claim 6, wherein a surface roughness of the second dielectric layer portion is lower than a surface roughness of the third dielectric layer portion.

8. The PDP as claimed in claim 1, wherein the first protective layer portions, the second protective layer portions, and the third protective layer portions substantially include the same material.

9. The PDP as claimed in claim 8, wherein the first protective layer portions, the second protective layer portions, and the third protective layer portions include magnesium oxide (MgO).

10. The PDP as claimed in claim 1, wherein each of the grooves is between pairs of the discharge electrode pairs.

11. The PDP as claimed in claim 1, wherein each of the grooves corresponds to a respective discharge cell.

12. The PDP as claimed in claim 1, wherein each of the grooves has a rectangular cross-section.

13. The PDP as claimed in claim 1, wherein the grooves are parallel to bus electrodes of the discharge electrodes.

14. The PDP as claimed in claim 1, wherein each discharge electrode includes a T-shaped transparent electrode.

15. A plasma display panel (PDP), comprising:
a rear substrate;
a front substrate in parallel to the rear substrate;
a plurality of barrier ribs between the front and rear substrates defining a plurality of discharge cells;
a plurality of discharge electrode pairs spaced apart from one another on the front substrate;
a front dielectric layer having a first front dielectric layer portion and a second front dielectric layer portion;
a plurality of grooves in the front dielectric layer, sidewalls of the grooves corresponding to the first front dielectric layer portion of the front dielectric layer;
a protective layer having first protective layer portions on sidewalls of the grooves, second protective layer portions on the second front dielectric layer portion of the front dielectric layer, and third protective layer portions on substantially horizontal surfaces of the grooves, and wherein at least one thickness of the first protective layer portions and the third protective layer portions is larger than a thickness of the second protective layer portions;
a plurality of address electrodes on the rear substrate;
a plurality of phosphor layers inside the discharge cells; and
a discharge gas in the discharge cells.

16. The plasma display panel as claimed in claim 15, wherein a surface roughness of the second front dielectric layer portion of the front dielectric layer is lower than a surface roughness of the first front dielectric layer of the front dielectric layer.

17. The plasma display panel as claimed in claim 15, wherein the grooves are in communication with the front substrate.

18. The plasma display panel as claimed in claim 15, wherein each of the grooves is between an X electrode of one pair of discharge electrodes and a Y electrode of another pair of discharge electrodes.

19. The plasma display panel as claimed in claim 15, wherein the grooves are discontinuous segments.

20. The plasma display panel as claimed in claim 19, wherein a single groove corresponds to a single discharge cell.
